(19) United States
(12) Patent Application Publication
(10) Pub. No.: US 2005/0153513 A1
(43) Pub. Date: Jul. 14, 2005

(54) Method of forming a dielectric layer for a non-volatile memory cell and method of forming a non-volatile memory cell having the dielectric layer

(76) Inventors: Woong Lee, Seoul (KR); Young-Sub You, Pyoungtack-si (KR); Hun-Hyeoung Leam, Yongin-si (KR); Ki-Su Na, Yongin-si (KR); Man-Sug Kang, Suwon-si (KR); Jung-Hwan Kim, Suwon-si (KR); Jai-Dong Lee, Suwon-si (KR)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 10/992,841

(22) Filed: Nov. 22, 2004

(30) Foreign Application Priority Data
Jan. 8, 2004 (KR) 2004-1144

(51) Int. Cl. H01L 21/8238; H01L 21/336

(52) U.S. Cl. 438/287

(57) ABSTRACT

A method of forming a dielectric layer for a non-volatile memory cell is disclosed. According to the method, a dielectric layer is formed by successively forming a lower oxide layer, a nitride layer and an upper oxide layer on a semiconductor substrate. The lower and upper oxide layers are formed using a radical oxidation process. A method of forming a non-volatile memory cell having the dielectric layer is also disclosed.

### BACKGROUND OF THE INVENTION

1. Field of the Invention

The present invention relates generally to a method of forming a dielectric layer in a semiconductor device, and more particularly, to a method of forming a dielectric layer for a non-volatile memory cell.

A claim of priority is made to Korean Patent Application No. 2004-1144, filed on Jan. 8, 2004, the disclosure of which is incorporated herein by reference in its entirety.

2. Description of the Related Art

Semiconductor memory devices are roughly classified into two categories: volatile memory devices and non-volatile memory devices. Volatile memory devices, such as DRAM (dynamic random access memory) and SRAM (static random access memory), lose stored data unless a periodic refresh operation is performed, whereas non-volatile memory devices, such as flash memory and electrically-erasable programmable read-only memory (EEPROM), retain stored data without a periodic refresh operation.

In recent years, there has been a high demand for non-volatile memory devices allowing read and write operations, such flash memory. Therefore, a method of forming reliable, high quality, highly integrated non-volatile semiconductor memory devices is desirable.

FIG. 1 is a cross-sectional view illustrating a method of forming a gate structure in a conventional non-volatile memory cell.

Referring to FIG. 1, a memory cell having a gate stack structure 28 is shown. Forming the memory cell comprises forming a tunnel oxide layer 12 on a semiconductor substrate 10 having a device isolation layer 11, forming a floating gate 14 on tunnel oxide layer 12, forming a dielectric layer 22 on floating gate 14, and forming a control gate 26 on dielectric layer 22. Data is stored in the memory cell by applying an appropriate voltage to control gate 26 and semiconductor substrate 10 in order to move electrons into or out of floating gate 14.

Dielectric layer 22 generally has an oxide-nitride-oxide (ONO) structure comprising a lower oxide layer 16, a nitride layer 18, and an upper oxide layer 20. Dielectric layer 22 functions to maintain charge characteristics of floating gate 14, to transfer a voltage from control gate 26 to floating gate 14, and to insulate control gate 26 from floating gate 14.

The reliability of dielectric layers having an ONO structure is an issue of concern where semiconductor devices are highly integrated. For this reason, process technology for improving the reliability of dielectric layers has been developed.

Conventionally, lower oxide layer 16 and upper oxide layer 20 of dielectric layer 22 are formed using a thermal oxidation process. Unfortunately, the thermal oxidation process is prone to causing a defect at the interface between floating gate 14 and lower oxide layer 16 due to an effect of a thermal budget in a high temperature treatment. Furthermore, the thermal oxidation process is time-consuming and it provides little control over the thickness of the resulting oxide layers. Therefore, in an effort to successfully address the problems of the thermal oxidation process, a low temperature treatment process, such as a chemical vapor deposition (CVD), is often used to form the oxide layers.

A method of forming an oxide layer using a CVD process is disclosed, for example, in U.S. Pat. No. 6,008,091.

Forming lower and upper oxide layers 16 and 20 using the low temperature treatment of the CVD process typically comprises using a low pressure chemical vapor deposition (LPCVD) method. The LPCVD typically comprises flowing SiH₄ and N₂O gases at a temperature of about 700 to 800° C. and a pressure of about 400 to 750 mTorr to form an oxide layer and flowing a N₂O gas at a temperature of 830° C. and a pressure of about 760 torr to densify the oxide layers.

An oxide layer formed by the foregoing LPCVD method has a low density and generally suffers from a number of defects. For example, gas materials often remain inside the oxide layer or the oxide layer becomes otherwise contaminated. Furthermore, a memory cell formed using this method often experiences a leakage current, which consumes charge stored on floating gate 14. Therefore, it is disadvantageous to fabricate a highly-integrated memory device using the LPCVD method described above.

FIG. 2 is a graph illustrating changes to threshold voltages (Vₜₕ) of two not-or (NOR) memory devices following a thermal treatment process. The purpose of the graph is to illustrate data retention characteristics of memory devices formed using two different processes.

Referring to FIG. 2, threshold voltages are measured before and after thermal treatment of the NOR memory devices at a temperature of 300° C. for 72 hours. The two rightmost curves in FIG. 2 show initial threshold voltages for NOR devices formed using a CVD process and a thermal oxidation process and the two leftmost curves show final threshold voltages for the same NOR devices after thermal treatment. Vₜₕ for the NOR memory device formed using the CVD process is significantly different from Vₜₕ for the NOR memory device formed using the thermal oxidation process. Specifically, Vₜₕ for a memory device having a dielectric layer with oxide layers formed using the CVD process is 2.96V, whereas Vₜₕ for a memory device having a dielectric layer with oxide layers formed using the thermal oxidation process is 2.26V. In other words, the change in threshold voltage for the memory device having a dielectric layer formed using the CVD process is higher than the change in threshold voltage for the memory device having the dielectric layer formed using the thermal oxidation process by 0.7V. Therefore, the NOR memory device formed using the thermal oxidation process experiences better data retention than the NOR memory device formed using the CVD process.

Since problems exist in both the CVD and thermal oxidation processes, a method of forming a highly reliable, high-quality oxide layer suitable for a high degree of integration is desired. Such a method could replace the conventional methods of forming an oxide layer using thermal oxidation process or CVD.

### SUMMARY OF THE INVENTION

The present invention provides a method of forming a high-quality dielectric layer suitable for a highly integrated semiconductor device.

The present invention further provides a method of forming a dielectric layer having improved charge retention characteristics and high reliability relative to a conventional dielectric layer.

The present invention further provides a method of forming a dielectric layer having an adjustable thickness.

According to one aspect of the present invention, a method of forming a dielectric layer for a non-volatile memory cell is provided. The method comprises; forming a lower oxide layer using a radical oxidation process, forming a nitride layer on the lower oxide layer, and forming an upper oxide layer on the nitride layer using the radical oxidation process.

Preferably, the radical oxidation process comprises; reacting hydrogen (H₂) gas and oxygen (O₂) gas at a pressure of about 1 to 10 torr and a temperature of about 800 to 1050° C. Typically, the radical oxidation process is performed using an (in-situ steam generation) ISSG tool.

Preferably, the upper oxide layer is thicker than the lower oxide layer.

According to another aspect of the present invention, a method of forming a dielectric layer for a non-volatile memory cell is provided. The method comprises; forming a lower oxide layer using a radical oxidation process on a tunnel oxide layer, wherein the tunnel oxide layer is formed on a semiconductor substrate having a floating gate formed thereon. The method further comprises forming a nitride layer on the lower oxide layer, forming an upper oxide layer on the nitride layer using the radical oxidation process, and forming a control gate on the upper oxide layer.

Preferably, the radical oxidation process comprises; reacting hydrogen (H₂) gas and oxygen (O₂) gas at a pressure of about 1 to 10 torr and a temperature of about 800 to 1050° C. Typically, the radical oxidation process is performed using an (in-situ steam generation) ISSG tool.

Preferably, the upper oxide layer is thicker than the lower oxide layer.

Therefore, according to the present invention, a high-quality dielectric layer suitable for a highly integrated semiconductor device is formed. The dielectric layer formed according to the present invention has improved charge retention characteristics and high reliability relative to a conventional dielectric layer. Furthermore, according to the present invention, the thickness of the dielectric layer is adjustable.

### BRIEF DESCRIPTION OF THE DRAWINGS

The accompanying drawings illustrate one or more selected embodiments of the present invention and are incorporated in and constitute a part of this specification. In the drawings:

FIG. 1 is a cross-sectional view of a conventional memory cell having a dielectric layer;

FIG. 2 is a graph illustrating charge retention characteristics of memory devices having oxide layers formed using two different conventional methods;

FIGS. 3 through 8 are cross-sectional views illustrating the formation of a dielectric layer for a non-volatile memory cell according to one embodiment of the present invention; and,

FIG. 9 is a graph illustrating a qualitative comparison between an oxide layer (labeled ISSG) formed according to one embodiment of the present invention and an oxide layer (labeled Gnox) formed by a conventional method.

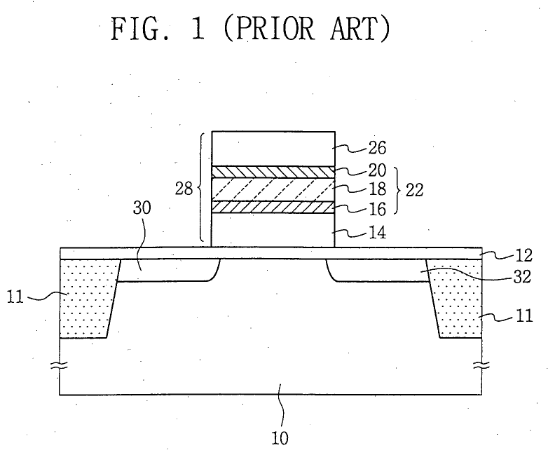

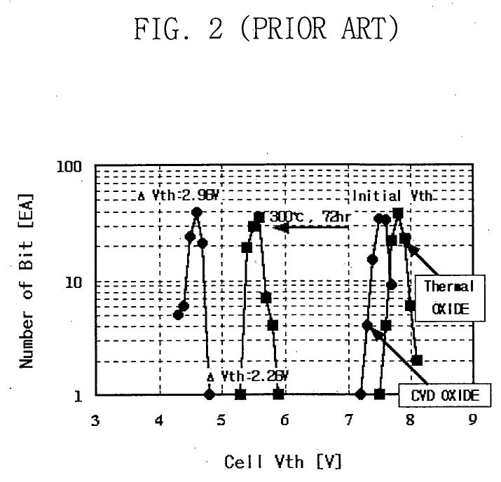

### DETAILED DESCRIPTION OF THE INVENTION

The present invention will now be described more fully with reference to the accompanying drawings, in which several preferred embodiments of the invention are shown. In the drawings, the thickness of layers and regions is exaggerated for clarity. Like reference numerals refer to like elements throughout the specification.

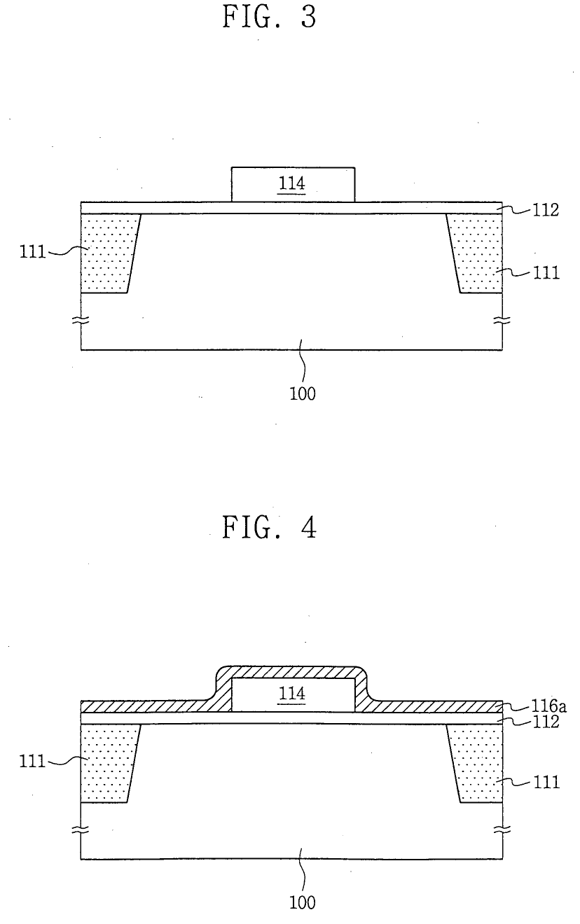

FIGS. 3 through 8 are cross-sectional views illustrating a method of forming a dielectric layer for a non-volatile memory cell according to one embodiment of the present invention.

Referring to FIG. 3, a tunnel oxide layer 112 is formed on a semiconductor substrate 100 having a device isolation layer 111. Tunnel oxide layer 112 preferably comprises an oxide layer or an oxynitride layer and has a preferred thickness of about 40 to 100 Å.

A floating gate 114 is formed on tunnel oxide layer 112. Floating gate 114 is preferably formed from a polysilicon layer having a thickness of about 600 to 700 Å. Floating gate 114 is formed using an LPCVD method, wherein the polysilicon layer is doped with a high concentration of impurities using a conventional doping method, such as diffusion, ion implantation, or in-situ doping. A photolithography process and an etching process are further performed on the polysilicon layer.

Referring to FIG. 4, a lower oxide layer 116a is formed on floating gate 114 and tunnel oxide layer 112. Lower oxide layer 116a preferably is formed by a radical oxidation process of reacting hydrogen (H₂) gas and oxygen (O₂) gas at low pressure on exposed surfaces of floating gate 114 and tunnel oxide layer 112. Lower oxide layer 16a typically has a thickness of 30 to 70 Å, and preferably it has a thickness of about 60 Å. One advantage of forming lower oxide layer 116a using the radical oxidation process rather than a conventional method is that it allows the thickness of lower oxide layer 116a to be adjusted. Being able to adjust the thickness of the lower oxide layer 116a is advantageous because it allows the electrical characteristics of the dielectric layer to be fine-tuned.

Lower oxide layer 116a is preferably formed at a low pressure of about 1 to 10 torr and a temperature of about 800 to 1050° C. The radical oxidation process yields a dense oxide layer, which has the advantage minimizing leakage current in lower oxide layer 116, even where lower oxide layer 116a is thin.

The radical oxidation method is typically performed using an in-situ steam generation (ISSG) tool. The radical oxidation method using the ISSG tool reacts oxygen gas (O₂) with added hydrogen gas (H₂). This combination of gases uses internal-combustion thermal oxidation to generate steam which is applied to a heated semiconductor substrate.

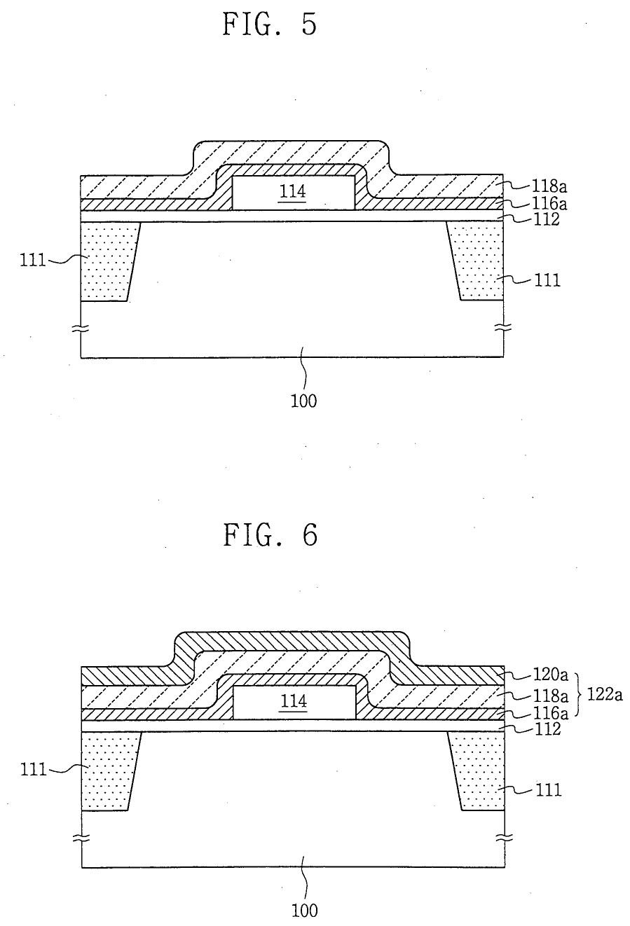

Referring to FIG. 5, a nitride layer 118a is formed on lower oxide layer 116a. Nitride layer 118a is formed to prevent leakage currents and is typically formed by a conventional method such as a LPCVD method. Preferably, nitride layer 118a has a thickness of about 60 to 100 Å.

Referring to FIG. 6, an upper oxide layer 120a is formed on nitride layer 118a. Upper oxide layer 120a is preferably formed by the same general method used to form lower oxide layer 116a. Upper oxide layer typically has a thickness of 50 to 100 Å, and preferably it has a thickness of about 70 Å. Additionally, upper oxide layer 120a is preferably thicker than lower oxide layer 116a.

Lower dielectric layer 116a, nitride layer 118a, and upper oxide layer 120a are collectively referred to as a dielectric layer 122a. Dielectric layer 122a has an ONO structure.

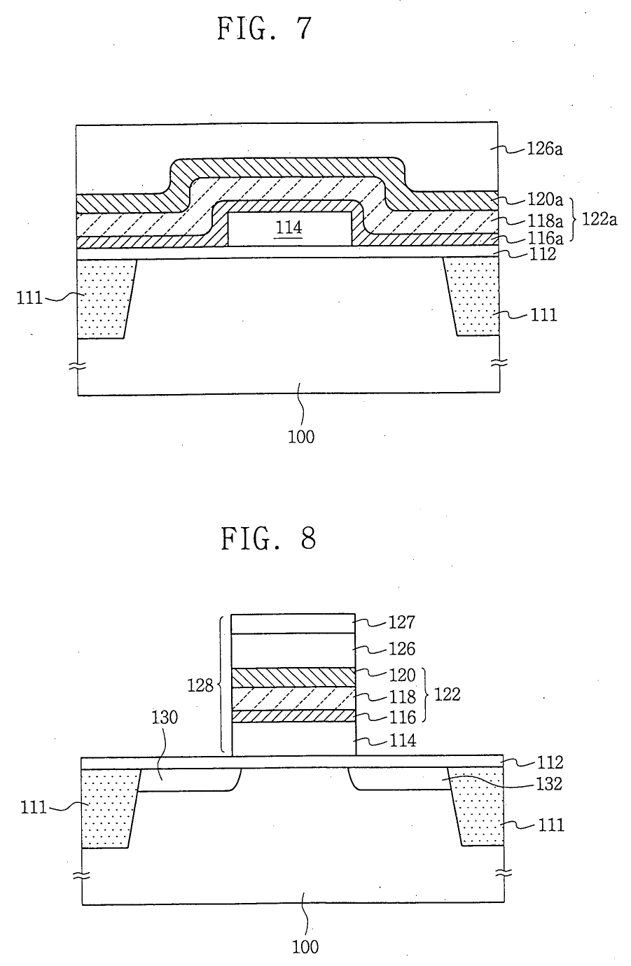

Referring to FIG. 7, a polysilicon layer 126a is formed on dielectric layer 122a using a LPCVD method. Polysilicon layer 126a is then doped with impurities using a conventional doping method such as diffusion, ion implantation, or in-situ doping.

Referring to FIG. 8, a metal silicide layer 127a (not shown) is formed on polysilicon layer 126a to reduce the resistance of a control gate formed from polysilicon layer 126a in a subsequent procedure. Metal silicide layer 127a is formed using a deposition process.

Following the formation of metal silicide layer 127a on polysilicon layer 126a, a gate stack structure 128 is formed by performing a photolithography process and an etching process to remove portions of dielectric layer 122a, polysilicon layer 126a, and metal silicide layer 127a. Gate stack structure 128 comprises floating gate 114, a dielectric layer 122, a control gate 126, and a metal silicide layer 127. Dielectric layer 122, which has an ONO structure, comprises a lower oxide layer 116, a nitride layer 118, and an upper oxide layer 120.

In FIG. 8, lower oxide layer 116, nitride layer 118, upper oxide layer 120, dielectric layer 122, control gate 126, and metal silicide layer 127 correspond respectively to lower oxide layer 116a, nitride layer 118a, upper oxide layer 120a, dielectric layer 122a, polysilicon layer 126a, and metal silicide layer 127a having portions removed by the photolithography process and the etching process.

After gate stack structure 128 is formed, a source 130 and a drain 132 are formed in semiconductor substrate 100.

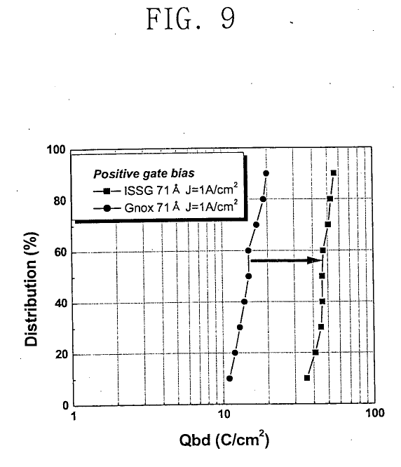

FIG. 9 is a graph illustrating a qualitative comparison between an oxide layer (labeled ISSG) formed according to one embodiment of the present invention and an oxide layer (labeled Gnox) formed by a conventional method. In FIG. 9, charge-to-breakdown (Qbd) is measured along an x-axis and a failure rate is measured along a y-axis. In other words, FIG. 9 shows failure rate as a function of Qbd. Qbd is measured for oxide layers having a thickness of 71 Å and a current density used to measure Qbd is 1A/cm².

Referring to FIG. 9, Qbd in the oxide layer formed according to the embodiment of the present invention is significantly higher than Qbd in the oxide layer formed by the conventional method. Using Qbd as a quality metric, the oxide layer formed according to the embodiment of the present invention is clearly of a higher quality than the oxide layer formed by the conventional method.

According to the present invention, an oxide layer having a high charge-to-breakdown and low leakage current relative to a conventional oxide layer is formed. A dielectric layer formed according to the present invention has improved charge characteristics relative to a conventional dielectric layer and is thickness adjustable. Due to these and other advantages, the method of the present invention is useful in forming highly integrated semiconductor devices.

The preferred embodiments disclosed in the drawings and the corresponding written description are teaching examples. Those of ordinary skill in the art will understand that various changes in form and details may be made to the exemplary embodiments without departing from the scope of the present invention which is defined by the following claims.

1. A method of forming a dielectric layer for a non-volatile memory cell, comprising:
forming a lower oxide layer using a radical oxidation process;
forming a nitride layer on the lower oxide layer; and,
forming an upper oxide layer on the nitride layer using the radical oxidation process.

2. The method of claim 1, wherein the radical oxidation process comprises:
reacting hydrogen (H₂) gas and oxygen (O₂) gas at a pressure of about 1 to 10 torr and a temperature of about 800 to 1050° C.

3. The method of claim 2, wherein the upper oxide layer is thicker than the lower oxide layer.

4. The method of claim 3, wherein the radical oxidation process is performed using an (in-situ steam generation) ISSG tool.

5. A method of forming a dielectric layer for a non-volatile memory cell, comprising:
forming a lower oxide layer using a radical oxidation process on a semiconductor substrate having a floating gate formed thereon, wherein a tunnel oxide layer is interposed between the lower oxide layer and the semiconductor substrate;
forming a nitride layer on the lower oxide layer; and,
forming an upper oxide layer on the nitride layer using the radical oxidation process.

6. The method of claim 5, wherein the radical oxidation process comprises:
reacting hydrogen (H₂) gas and oxygen (O₂) gas at a pressure of about 1 to 10 torr and a temperature of about 800 to 1050° C.

7. The method of claim 7, wherein the upper oxide layer is thicker than the lower oxide layer.

8. The method of claim 7, wherein the radical oxidation process is performed using an (in-situ steam generation) ISSG tool.

9. The method of claim 8, further comprising:
forming a control gate on the upper oxide layer.

10. A method of forming a non-volatile memory cell, comprising:
forming a tunnel oxide layer on a semiconductor substrate having a device isolation layer;
forming a floating gate on the tunnel oxide layer;
forming a lower oxide layer on the floating gate and the tunnel oxide layer using a radical oxidation process;
forming a nitride layer on the lower oxide layer;
forming an upper oxide layer on the nitride layer using the radical oxidation process;
forming a control gate on the upper oxide layer.

11. The method of claim 10, wherein the radical oxidation process comprises:
reacting hydrogen (H₂) gas and oxygen (O₂) gas at a pressure of about 1 to 10 torr and a temperature of about 800 to 1050° C.

12. The method of claim 11, wherein the upper oxide layer is thicker than the lower oxide layer.

13. The method according to claim 12, wherein the radical oxidation process is performed using an (in-situ steam generation) ISSG tool.

14. The method of claim 12, wherein forming the floating gate comprises:
forming a polysilicon layer having a thickness of about 600 to 700 Å;
doping the polysilicon layer with a high concentration of impurities; and,
performing a photolithography process or an etching process on the polysilicon layer.

15. The method of claim 12, wherein forming the control gate comprises:
forming a polysilicon layer on the upper oxide layer; and,
doping the polysilicon layer with impurities.

16. The method of claim 15, further comprising:
forming a source and a drain on the semiconductor substrate.

17. The method of claim 15, further comprising:
forming a metal silicide layer on the control gate.
